(19) United States
(12) Patent Application Publication
(10) Pub. No.: US 2026/0219523 A1
(43) Pub. Date: Jul. 30, 2026

(54) HIGH-SPEED AND LOW MODULATION LOSS MULTI-RING MODULATOR

(71) Applicant: XILINX, INC., San Jose, CA (US)

(72) Inventor: Zakriya MOHAMMED, San Jose, CA (US)

(21) Appl. No.: 19/039,511

(22) Filed: Jan. 28, 2025

(51) Int. Cl. G02F 1/025; H01L 23/34; H01L 25/16

(52) U.S. Cl. CPC G02F 1/025; H10W 40/10; H10W 90/00

(57) ABSTRACT

High-speed and low modulation loss multi-ring modulators may be implemented in an integrated circuit (IC) device, and may include a throughput waveguide, multiple micro-ring modulators (MRMs) optically coupled to the throughput waveguide, and an inductor coupled to a signal pad and to N-type junctions of the MRMs. N junctions of the MRMs are coupled to one another, and P junctions of the MRMs are coupled to one another. The MRMs may be designed and/or tuned to resonate at the same wavelength. The N and P junctions may include lateral/horizontal junctions, vertical junctions, and/or interdigitated junctions. The IC device may further include a substrate and heater elements disposed adjacent to the MRMs, and a surface of the substrate facing the heater elements may have recesses aligned with the heater elements.

### TECHNICAL FIELD

Examples of the present disclosure generally relate to high-speed and low modulation loss multi-ring modulators.

### BACKGROUND

Silicon micro-ring modulators (MRMs) are pivotal elements in photonics integrated circuits, facilitating high-speed and cost-efficient optical interconnects and optical computing systems. For optimal performance in optical interconnect applications, MRMs are required to exhibit a substantial optical modulation amplitude (OMA). A high OMA indicates a significant modulation depth and a low insertion loss (IL), which together enhance receiver sensitivity and minimize the power penalty (modulation loss). However, there is an inherent trade-off between modulation bandwidth and OMA in MRMs: a reduction in modulation loss typically leads to a decrease in modulation bandwidth.

### SUMMARY

Techniques for high-speed and low modulation loss multi-ring modulators are described. One example is an integrated circuit device that includes a throughput waveguide, multiple micro-ring modulators (MRMs) optically coupled to the throughput waveguide, and an inductor coupled to a signal pad and to the N-type junctions of the MRMs. P junctions of the MRMs may be coupled to one another, and N junctions of the MRMs may be coupled to one another. The MRMs may be designed and/or tuned to resonant at the same wavelength.

Another example described herein is an integrated circuit device that includes a functional circuit and an optical transceiver that modulates an optical signal based on data from the functional circuit, where the optical transceiver includes a throughput waveguide, multiple micro-ring modulators (MRMs) optically coupled to the throughput waveguide, and an inductor coupled to a signal pad and to the N-type junctions of the MRMs. P junctions of the MRMs may be coupled to one another, and N junctions of the MRMs may be coupled to one another. The MRMs may be designed and/or tuned to resonant at the same wavelength.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 depicts an integrated circuit (IC) device that includes cascaded MRMs designed and/or tuned to resonate at the same wavelength (e.g., having the same radius R), according to an embodiment.

FIG. 2 depicts the MRMs, according to an embodiment.

FIG. 3 depicts the MRMs according to another embodiment.

FIG. 4 depicts the MRMs according to another embodiment.

FIG. 5 depicts the MRMs according to another embodiment.

FIG. 6 depicts a floorplan/layout of the IC device, according to an embodiment.

FIG. 7 depicts the floorplan/layout of the IC device further including a floorplan/layout of an inductor, according to an embodiment.

FIG. 8 depicts an expanded view of the floorplan/layout of a one of the MRM of the IC device, according to an embodiment.

FIG. 9 depicts MRMs of the IC device having recesses (e.g., in surface of a substrate), adjacent to heater elements, according to an embodiment.

FIG. 10 depicts the IC device in which a surface of a substrate has recesses aligned with the heater elements, according to an embodiment.

FIG. 11A depicts a graph of simulated drop port response of a single MRM, according to an embodiment.

FIG. 11B depicts a graph of simulated through port response of the single MRM, according to an embodiment.

FIG. 11C depicts a portion of the graph of FIG. 11B, according to an embodiment.

FIG. 12 depicts graphs of modulation efficiency of the single MRM, according to an embodiment.

FIG. 13A depicts a graph of optical transmission power versus wavelength, for the single MRM, according to an embodiment.

FIG. 13B depicts a graph of optical modulation amplitude (OMA) versus wavelength, for the single MRM, according to an embodiment.

FIG. 13C depicts a portion of the graph of FIG. 12B, according to an embodiment.

FIG. 13D depicts results, for the single MRM, according to an embodiment.

FIG. 14A depicts an eye diagram for the single MRM, according to an embodiment.

FIG. 14B depicts an eye diagram for the single MRM, according to another embodiment.

FIG. 15A depicts a graph of throughput response versus wavelength, for dual cascaded MRMs, according to an embodiment.

FIG. 15B depicts a portion of the graph of FIG. 15A, according to an embodiment.

FIG. 15C depicts results for the dual cascaded MRMs, according to an embodiment.

FIG. 16 depicts graphs of modulation efficiency of the dual cascaded MRMs, according to an embodiment.

FIG. 17A depicts a graph of optical transmission power versus wavelength for the dual cascaded MRMs, according to an embodiment.

FIG. 17B depicts a graph of OMA versus wavelength for the dual cascaded MRMs, according to an embodiment.

FIG. 17C depicts a portion of the graph of FIG. 17B, according to an embodiment.

FIG. 17D depicts results for the dual cascaded MRMs, according to an embodiment.

FIG. 18A depicts an eye diagram for the dual cascaded MRMs, according to an embodiment.

FIG. 18B depicts an eye diagram for the dual cascaded MRMs, according to another embodiment.

FIG. 19A depicts a graph of throughput response versus wavelength of a triplet of cascaded MRMs, according to an embodiment.

FIG. 19B depicts a portion of the graph of FIG. 19A, centered near 1317 nm, according to an embodiment.

FIG. 19C depicts results, according to an embodiment.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the features or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Embodiments herein describe high-speed and low modulation loss multi-ring modulators.

Silicon photonics offers a compelling solution for high-speed on-chip optical interconnects, enabling advanced, cost-effective optical communication and computing systems. For effective modulation and transmission of high-speed optical signals, modulators should operate with a high optical bandwidth and minimal modulation loss. High modulation depth is important because increased modulation loss adversely affects the link budget, necessitating higher laser power to compensate.

The overall bandwidth of a micro-ring modulator (MRM) determines the maximum supported data rate. The overall bandwidth is a function of optical bandwidth and electrical bandwidth. The overall bandwidth may be expressed as:

$$\frac{1}{{f}_{T}^{2}} = \frac{1}{{f}_{o p t}^{2}} + \frac{1}{{f}_{e l e}^{2}} ,$$

where fₒₚₜ
fₑₗₑ is the electrical bandwidth.

Optical bandwidth may be expressed as:

$${f}_{o p t} = \frac{{w}_{0}}{2 π {Q}_{T}} , where$$

$${Q}_{T} = {[ \frac{{λ}_{0} ln \vert σ \vert}{2 {π}^{2} r {n}_{g}} + \frac{{λ}_{0} a}{2 π {n}_{g}} ]}^{- 1} = \frac{λ}{Δ λ}$$

Electrical bandwidth is a function of a resistance/capacitance (RC) constant of a PN junction of the MRM. The electrical bandwidth may be expressed as 1/(2πRC).

To minimize modulation loss in micro-ring modulators (MRMs), it is essential to maximize the optical modulation amplitude (OMA), defined as the difference between the maximum (Pₘₐₓ) and minimum (Pₘᵢₙ) output optical power. The modulation loss of an MRM may be determined as OMA divided by the input optical power (Pₘₐₓ−Pₘᵢₙ/Pᵢₙ). Therefore, a large OMA corresponds to greater modulation depth and reduced modulation loss. MRMs with a sharp resonance (i.e., high quality factor Q) are typically preferred. However, high-Q resonators tend to exhibit long photon lifetimes, which limit the modulation bandwidth and make the device sensitive to temperature variations and fabrication inconsistencies. To address these challenges, MRMs based on low-Q resonators may be designed to achieve a wider modulation bandwidth, although this may result in reduced OMA. This creates a trade-off between modulation bandwidth and OMA, in that a reduction in modulation loss typically leads to a decrease in modulation bandwidth.

To address the trade-off between modulation loss and bandwidth limitations, dual MRMs may leverage the electromagnetically induced transparency (EIT) effect with precise wavelength detuning between the dual coupled low-Q MRMs. Detuning produces a narrow central peak in the optical spectrum, akin to the EIT phenomenon. Wavelength detuning to create a narrow central peak similar to EIT is challenging. Any deviation from the optimal detuning may degrade modulator performance and compromise the effectiveness of the EIT-like effect.

Alternatively, as disclosed herein, multiple cascaded MRMs designed and/or tuned to resonate at the same wavelength and/or to support a desired free-spectral range (FSR), provide increased slope efficiencies, which improves optical response/performance (i.e., increases optical bandwidth), with lower modulation loss at lower Q (i.e., higher optical bandwidth). Parallel PN junction resistances of the MRMs may reduce the overall resistance, and may increase the capacitance to a greater extent than the reduction in resistance, resulting in an overall higher RC constant, which reduces the electrical bandwidth. As further disclosed herein, the increased capacitance may be countered with an inductor to provide a system having a broad overall bandwidth that supports higher data rates. Multiple cascaded MRMs with inductive compensation extends bandwidth and reduces modulation loss. Multiple cascaded MRMs with inductive compensation may enhance high-speed operation and minimize modulation loss by improving DC extinction ratio, sidewall profile resonance, and broadening optical bandwidth.

In an example, each MRM includes an embedded p-i-n or PN junction to facilitate modulation. To optimize modulation efficiency, the device may be driven with a single-ended signal or a differential signal pair in a push-pull configuration. While driving the modulator with a push-pull signal pair may enhance modulation efficiency, it introduces complexity into the circuit design. Ensuring balanced and accurate signal pairs is important for achieving optimal performance and avoiding signal distortion.

Multiple cascaded MRMs with inductive compensation may be useful in a variety of applications including, without limitation, gigabit transceivers (e.g., co-packaged optical solutions for 800G and 1.6T transceivers based on Ethernet standards).

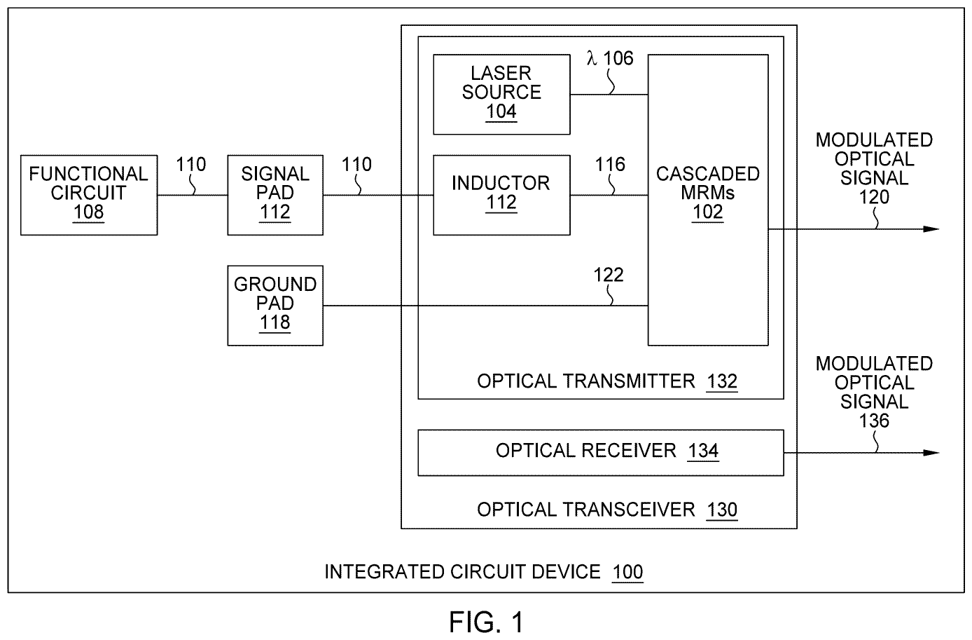

FIG. 1 depicts an integrated circuit (IC) device 100 that includes an optical transceiver 130, according to an embodiment. Optical transceiver 130 includes an optical transmitter 132 that includes multiple cascaded MRMs 102 that are designed and/or tuned to resonate at the same wavelength (e.g., having the same radius R). Optical transmitter 130 further includes a laser source 104 that provides an input optical signal 106 to MRMs 102.

IC device 100 further includes a functional circuit 108 that provides a data signal 110 to a signal pad 112, and optical transmitter 132 further includes an inductor 114 that conditions data signal 110. IC device 100 further includes a ground pad 118. MRMs 102 modulate optical signal 106 with conditioned data signal 116 to provide a modulated optical signal 120. Optical transceiver 130 may further include an optical receiver 134 that receives an optical signal 136.

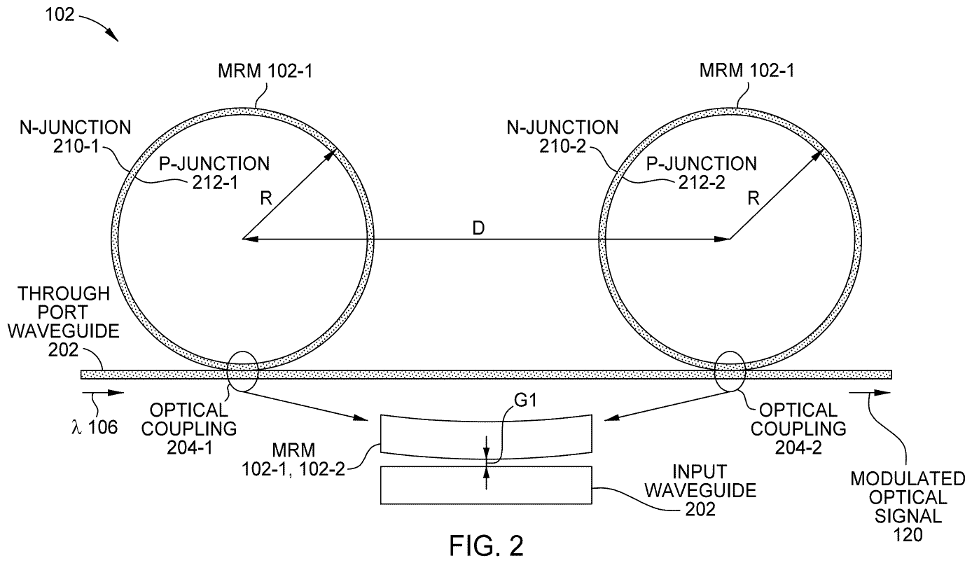

FIG. 2 depicts MRMs 102, according to an embodiment. In the example of FIG. 2, MRMs 102 include two MRMs 102-1 and 102-2 optically coupled to an throughput waveguide 202 at respective optical couplings 204-1 and 204-2 (collectively, optical couplings 204). At optical couplings 204, MRMs 102-1 and 102-2 are spaced from throughput waveguide 202 by a gap G1.

MRMs 102-1 and 102-2 may be designed and/or tuned to resonate at the same wavelength (i.e., a wavelength λ of optical signal 106). MRMs 102-1 and 102-2 may, for example, be designed to be identical to one another. In FIG. 2, MRMs 102-1 and 102-2 each have a radius R, and are spaced from one another by a spacing D. Spacing D may be selected as the minimum spacing permitted by a fabrication process design rule.

When optical signal 106 is transmitted into throughput waveguide 202, a portion of optical signal 106 couples into MRMs 102 due to the phenomenon of the evanescent field, provided that MRMs 102 are resonant at the wavelength λ of optical signal 106. The portions of optical signal 106 within MRMs 102 builds up in intensity over multiple round-trips due to constructive interference and total internal reflection (TIR). Portions of optical signal 106 within MRMs 102 are output to throughput waveguide 202 via optical coupling at optical couplings 204.

MRMs 102 include respective N junctions 210-1 and 210-2, and P junctions 212-1 and 212-2 to modulate the portion of optical signal 106 within MRMs 102 based on conditioned data signal 116. N junctions 210-1 and 210-2 may be coupled to one another, and P-junctions 212-1 and 212-2 may be coupled to one another. The N and P junctions may include lateral, vertical, and/or interdigitated junctions. The junction type(s) may be selected to maximize modulation efficiency. MRMs 102 may further include heater elements for tuning MRMs 102.

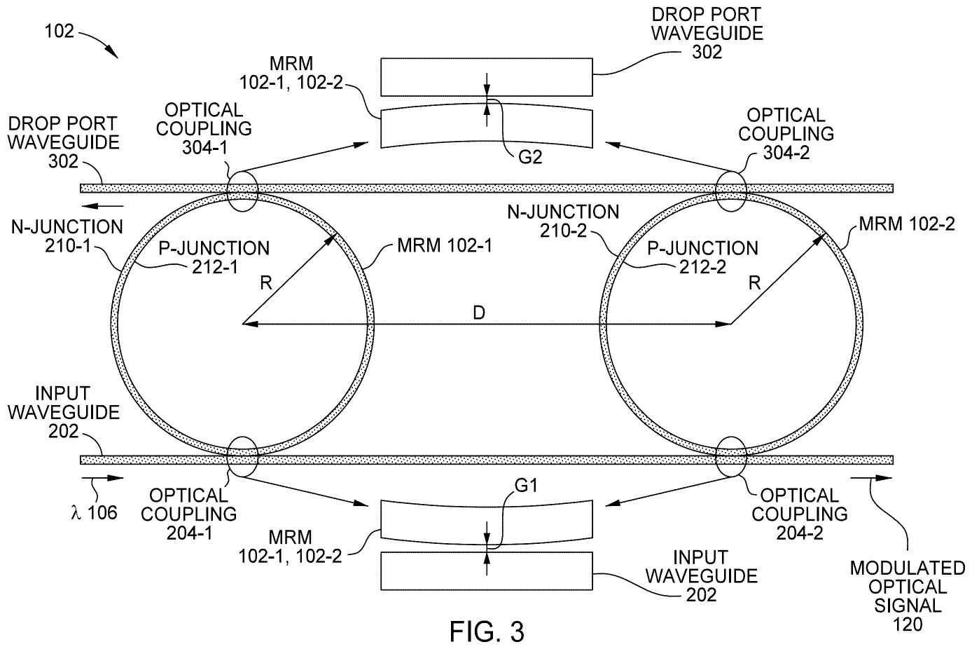

FIG. 3 depicts MRMs 102, according to another embodiment. In the example of FIG. 3, MRMs 102 include MRMs 102-1 and 102-2, optically coupled to throughput waveguide 202, such as described above with reference to FIG. 2. In FIG. 3, MRMs 102 are further optically coupled to a drop port waveguide 302 at respective optical couplings 304-1 and 304-2 (collectively, optical couplings 304). A portion of light/optical power within MRMs enters throughput waveguide 202 via optical couplings 204, and another portion of light/optical power within MRMs enters drop port waveguide 302 via optical couplings 304. At optical couplings 304-1 and 304-2, MRMs 102-1 and 102-2 are spaced from drop port waveguide 302 by a gap G2. Gap G2 may be greater than gap G1, such that more optical power of MRMs 102 couples to throughput waveguide 202 than drop port waveguide 302. In an example, gaps G1 and G2 are designed such that approximately 5% to 10% of the light/optical power of MRMs 102 couples to drop port waveguide 302. Drop port waveguide 302 may be useful for monitoring and tuning of MRMs 102.

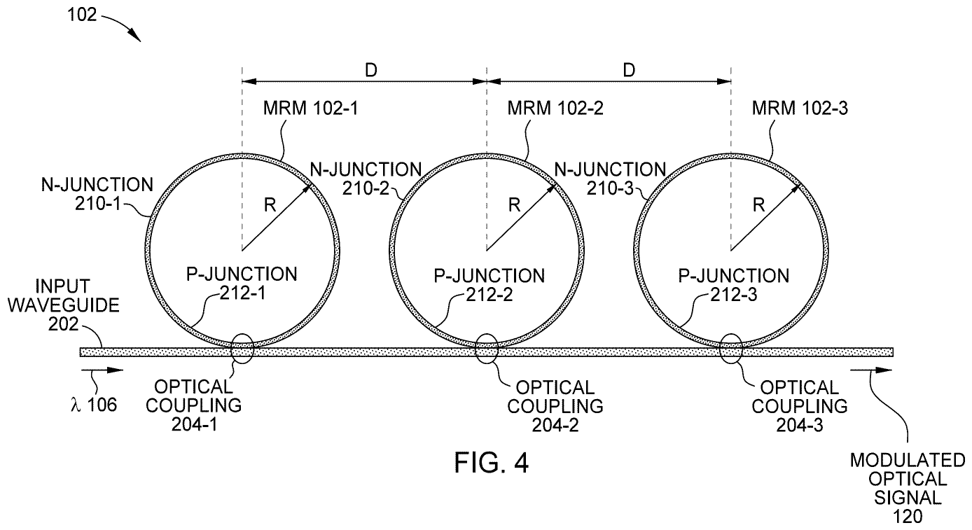

FIG. 4 depicts MRMs 102, according to another embodiment. In the example of FIG. 4, MRMs 102 include three MRMs 102-1, 102-2, and 102-3, optically coupled to throughput waveguide 202 at respective optical couplings 204-1, 204-2, and 204-3, such as described above with reference to FIG. 2. In FIG. 4, MRMs 102 include respective N junctions 210-1, 210-2, and 210-3, and P-junctions 212-1, 212-2, and 212-3 to modulate the portion of optical signal 106 within MRMs 102 based on conditioned data signal 116.

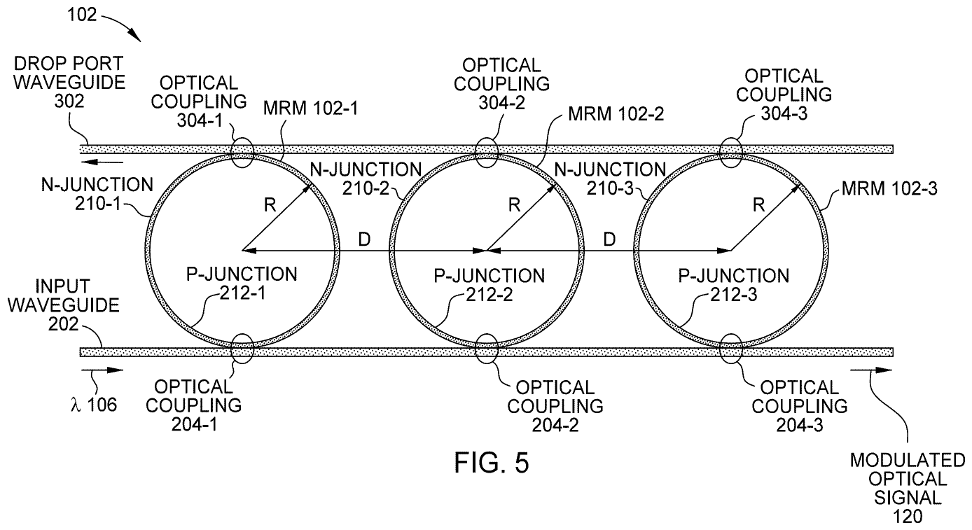

FIG. 5 depicts MRMs 102, according to another embodiment. In the example of FIG. 5, MRMs 102 include MRMs 102-1, 102-2, and 102-3, of FIG. 4, and drop port waveguide 302 of FIG. 3. MRMs 102-1, 102-2, and 102-3 are optically coupled to drop port waveguide 302 at respective optical couplings 304-1, 304-2, and 304-3, such as described above with reference to FIG. 3. IC device 100 may include more than three MRMs.

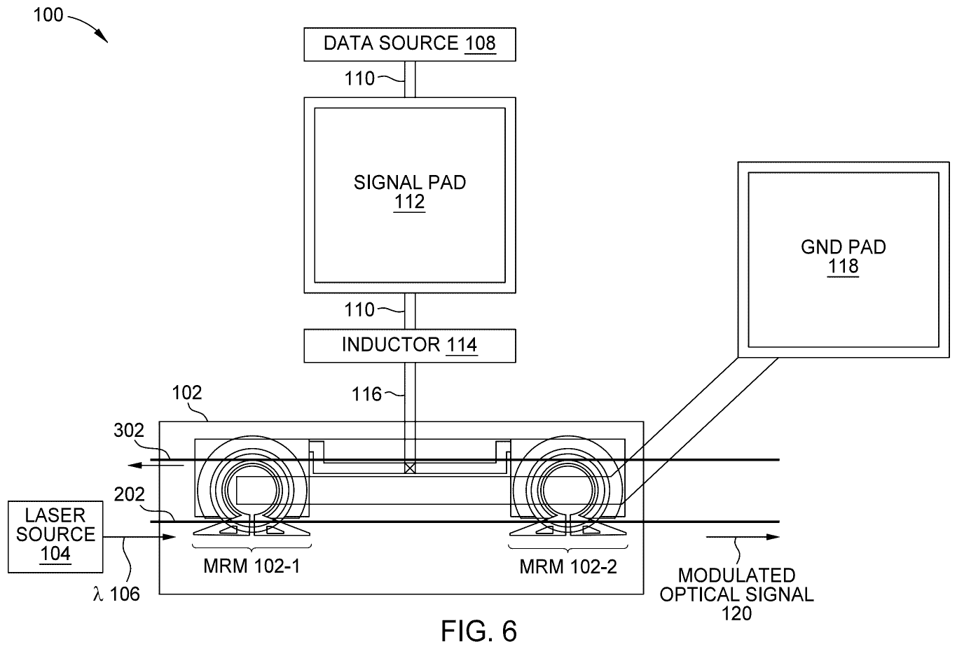

FIG. 6 depicts a floorplan/layout of IC device 100, according to an embodiment. Inductor 114 may be implemented in one or more metal layers of IC device 100.

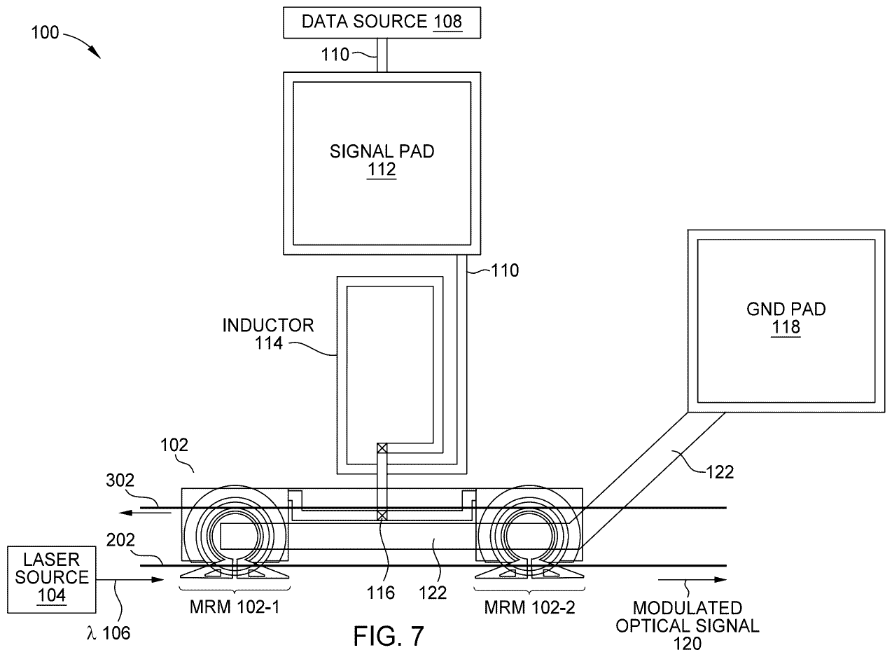

FIG. 7 depicts the floorplan/layout of IC device 100, further including a floorplan/layout of inductor 114, according to an embodiment.

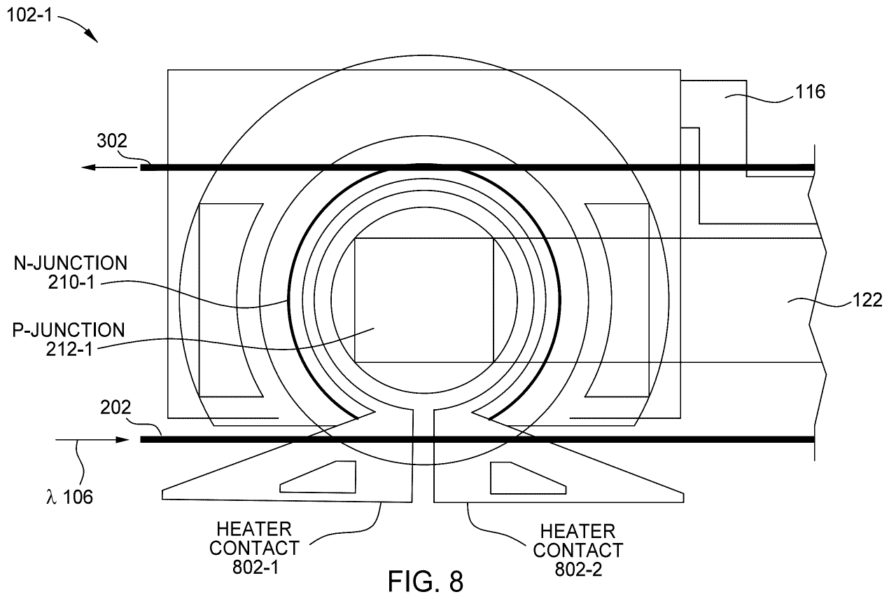

FIG. 8 depicts an expanded view of the floorplan/layout of MRM 102-1, according to an embodiment. In the example of FIG. 8, MRM 102-1 includes heater contacts 802-1 and 802-2.

When the P and N junctions of MRMs 102 are coupled to one another, the RC bandwidth is impacted as given by the equation f=½πCd(RL+RD), where Cd is a capacitance of MRMs 102, RL is an external load resistance, and RD is a diode resistance. The cascaded effect reduces the resistance and increases the capacitance. However, due to the presence of load resistance in a system implementation, the reduction of resistance does not cancel out the increased capacitance. To compensate for the increased capacitance, an inductance is added. A value of the inductance may be determined as 0.33Cd(RL+RD)\hat{ }2.

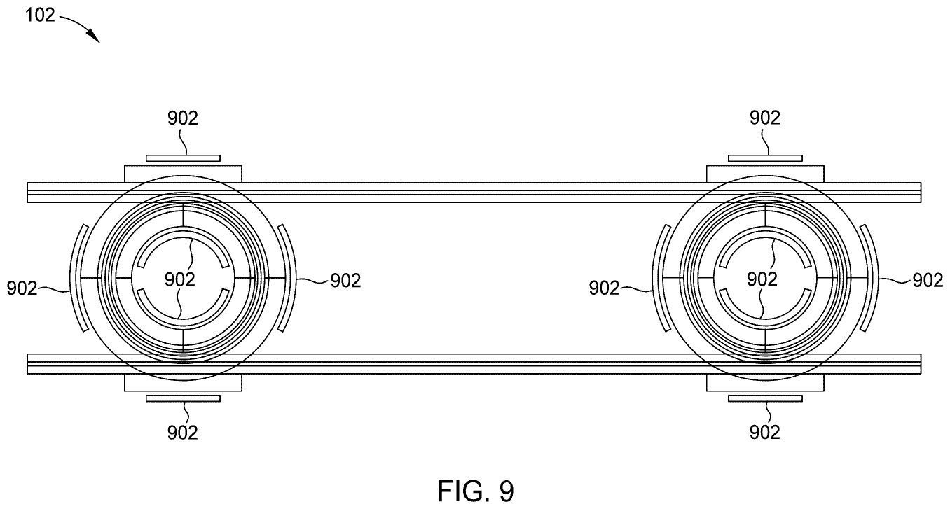

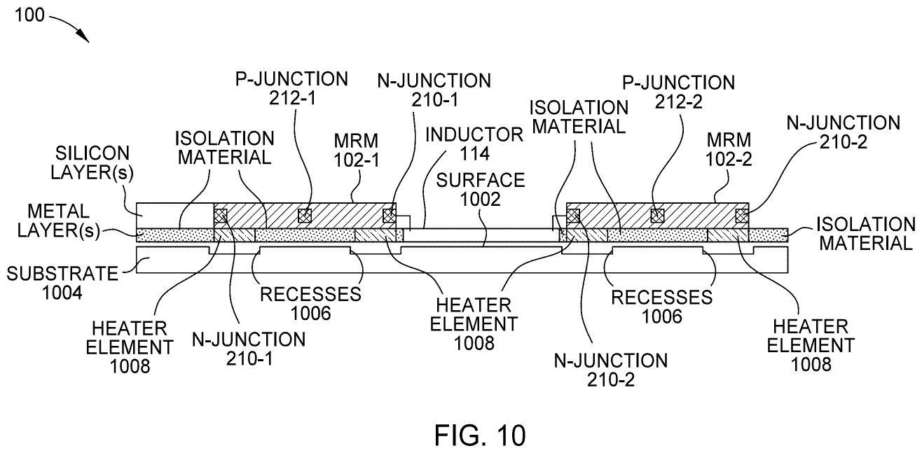

MRMs 102 may include respective heater elements and respective heater control circuitry, which may increase power consumption and/or may impact neighboring MRMs. IC device 100 may have recesses physically proximate to (e.g., adjacent to) the heater elements to reduce or preclude heat transfer amongst MRMs 102 and/or to conserve power consumption by the heater elements. FIG. 9 depicts MRMs 102-1 and 102-4 having recesses 902 (e.g., in surface of a substrate), adjacent to heater elements, according to an embodiment. FIG. 10 depicts IC device 100, in which a surface 1002 of a substrate 1004 has recesses 1006 aligned with heater elements 1008, according to an embodiment.

Performance improvements provided by cascaded MRMs 102 and inductor 114, relative to a single MRM, are described below.

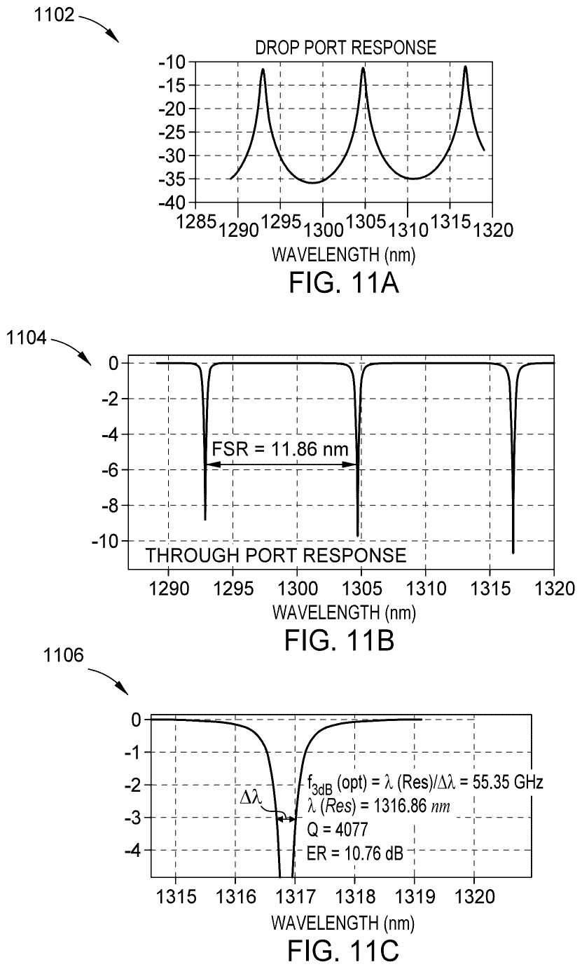

Simulated performance of a single MRM, designed and optimized for high-speed operation and high modulation efficiency, are provided below with reference to FIGS. 11A through 11C, FIG. 12, FIGS. 13A through 13D, 14A, and 14B. FIG. 11A depicts a graph 1102 of simulated drop port response of the single MRM, according to an embodiment. FIG. 11B depicts a graph 1104 of simulated through port response of the single MRM, according to an embodiment. FIG. 11C depicts a portion 1106 of graph 1104, centered near 1317 nm, according to an embodiment. The single MRM has a radius is 5.8 μm, which provides a free-spectral range (FSR) of 11.86 nm. A drop port gap G2 is selected to provide 5-7% power at the drop port for monitoring purposes. A through port gap G1 is selected to provide a quality factor of 4000 and an optical bandwidth of 55.35 GHZ. The DC extinction ratio (ER) of the single MRM is approximately 10 dB. The RC bandwidth of the single MRM is greater than 100 GHZ, and the overall electro-optic bandwidth of the single MRM is limited by optical bandwidth (photon lifetime).

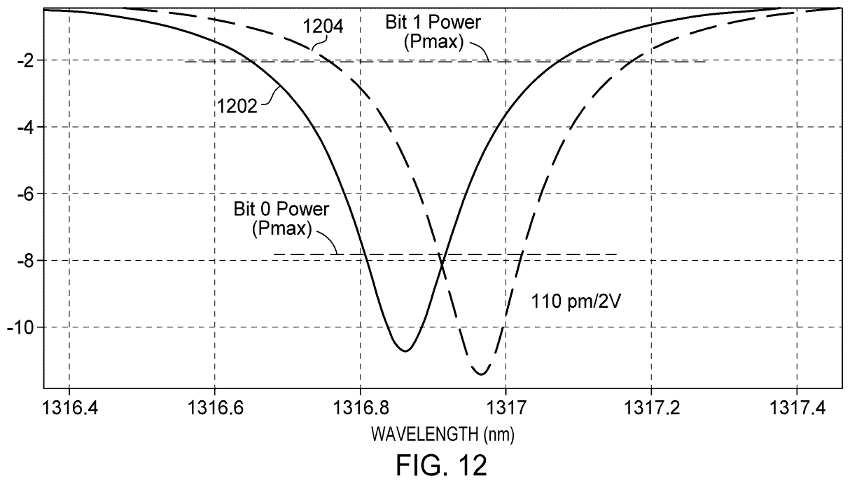

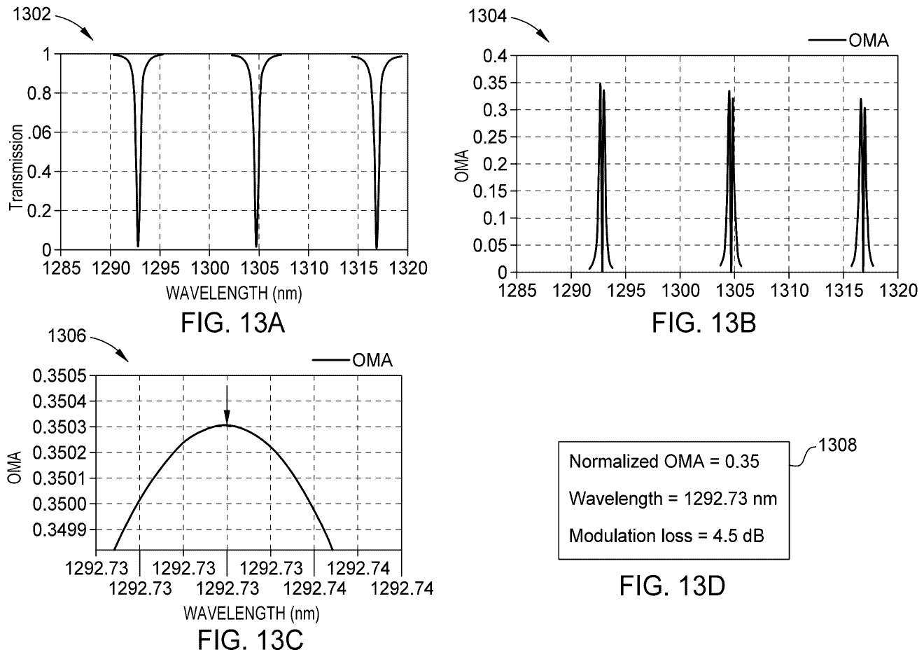

FIG. 12 depicts graphs 1202 and 1204 of modulation efficiency of the single MRM, according to an embodiment. Graph 1202 represents a 0-volt response. Graph 1204 represents a 2 volt response (i.e., a 2 volt shift relative to graph 1202). In the example of FIG. 12, the modulation efficiency is approximately 55 μm/V. If Q is lowered to increase the optical bandwidth, the modulation loss increases significantly, and may reduce the DC extinction ratio. The maximum bandwidth that can be achieved from the single MRM is 55.35 GHz. The wavelength that provides the maximum OMA may be selected or determined by maximizing DC OMA, such as depicted in FIGS. 13A through 13D. FIG. 13A depicts a graph 1302 of optical transmission power versus wavelength, according to an embodiment. FIG. 13B depicts a graph 1304 of OMA versus wavelength, according to an embodiment. FIG. 13C depicts a portion 1306 of graph 1304, according to an embodiment. FIG. 13D depicts results 1308, according to an embodiment.

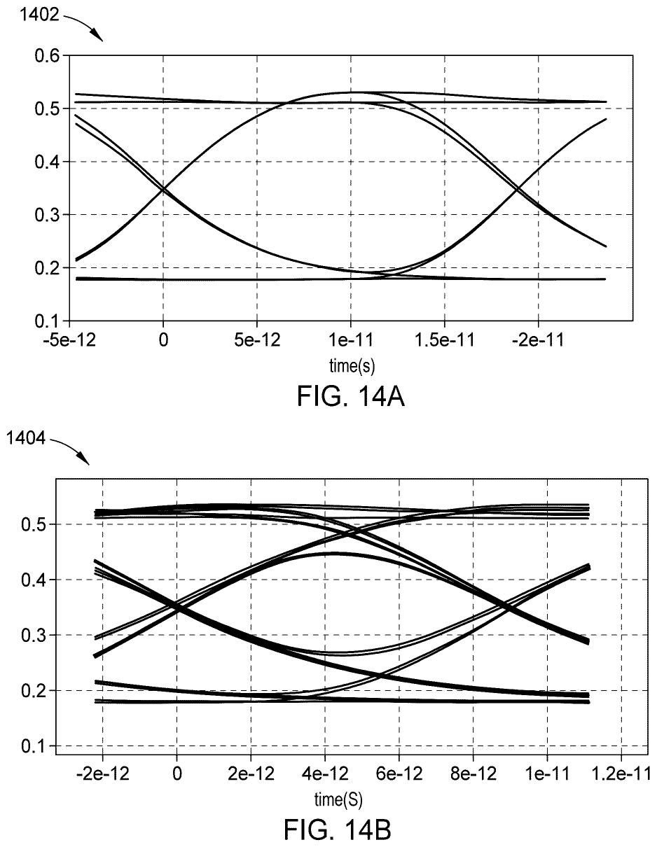

FIG. 14A depicts an eye diagram 1402 for the single MRM, according to an embodiment for which the input wavelength of 1316.88 nm, 0 dBm, and the data rate is 53 Gbits/second, for an OMA of 0.33 and a modulation loss of 4.8 dB. FIG. 14B depicts an eye diagram 1404 for the single MRM, according to another embodiment for which the input wavelength of 1316.88 nm, 0 dBm, and the data rate is 112 Gbits/second, for an OMA of 0.25 and a modulation loss of 6 dB. As depicted in FIGS. 14A and 14B, eye quality deteriorates at higher data rates due to limited optical bandwidth.

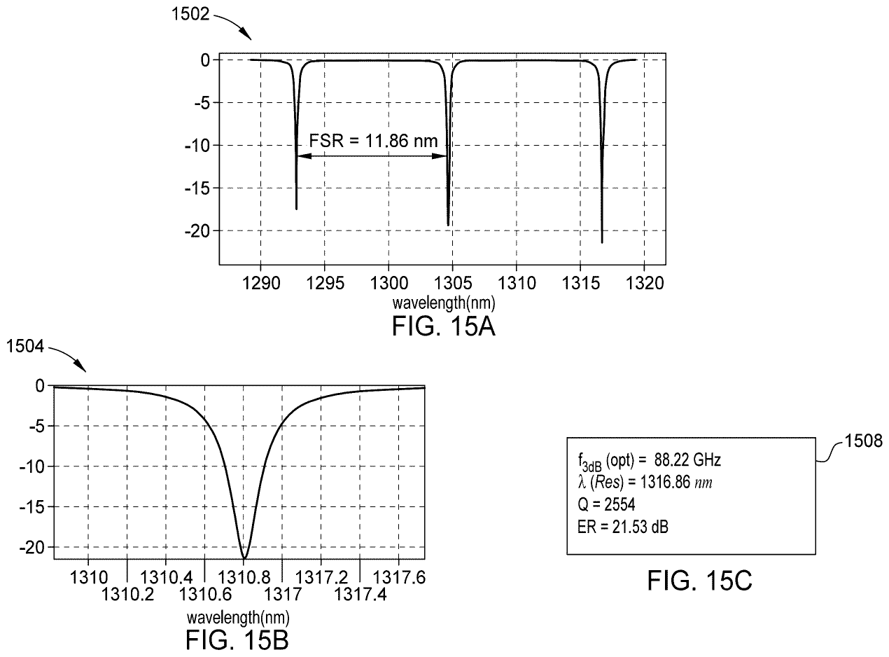

Simulation of optical transmitter 132 with dual cascaded MRMs 102 is described below with reference to FIGS. 15A through 15C, 16, 17A through 17D, 18A, and 18B. The dual cascaded MRMs are designed identical to the single MRMR described further above, and are separated from one another by distance D. FIG. 15A depicts a graph 1502 of throughput response versus wavelength, according to an embodiment. FIG. 15B depicts a portion 1504 of graph 1502, centered at 1316.8 nm, according to an embodiment. FIG. 15C depicts results 1508, according to an embodiment. The dual cascaded MRMs provide a FSR (i.e., optical bandwidth) of 88.2 GHz, with a quality factor of 2554 (due to the improved optical bandwidth). The DC ER of the dual cascaded MRMs increased to 21.53 dB (i.e., due to an increase in slope efficiency).

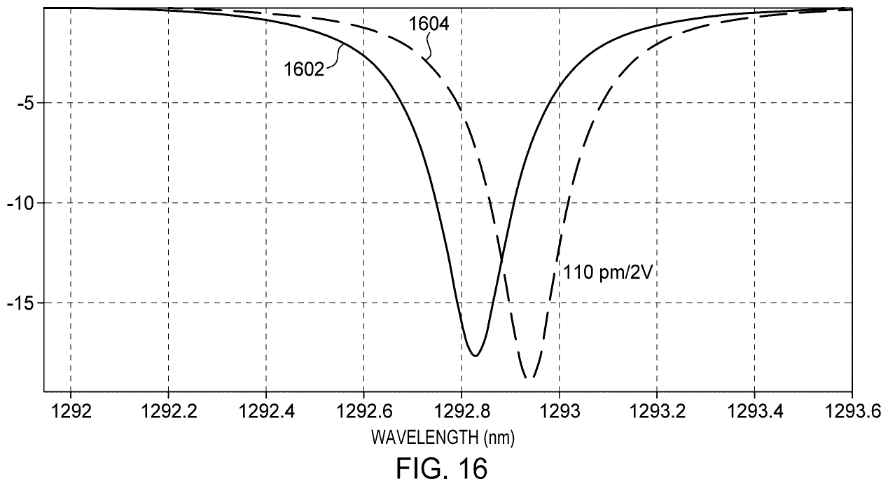

FIG. 16 depicts graphs 1602 and 1604 of modulation efficiency of the dual cascaded MRMs, according to an embodiment. Graph 1604 represents a 0-volt response. Graph 1604 represents a 2 volt response. Modulation efficiency of the dual cascaded MRMs remains the same as the single MRM because the P and N junctions remain the same.

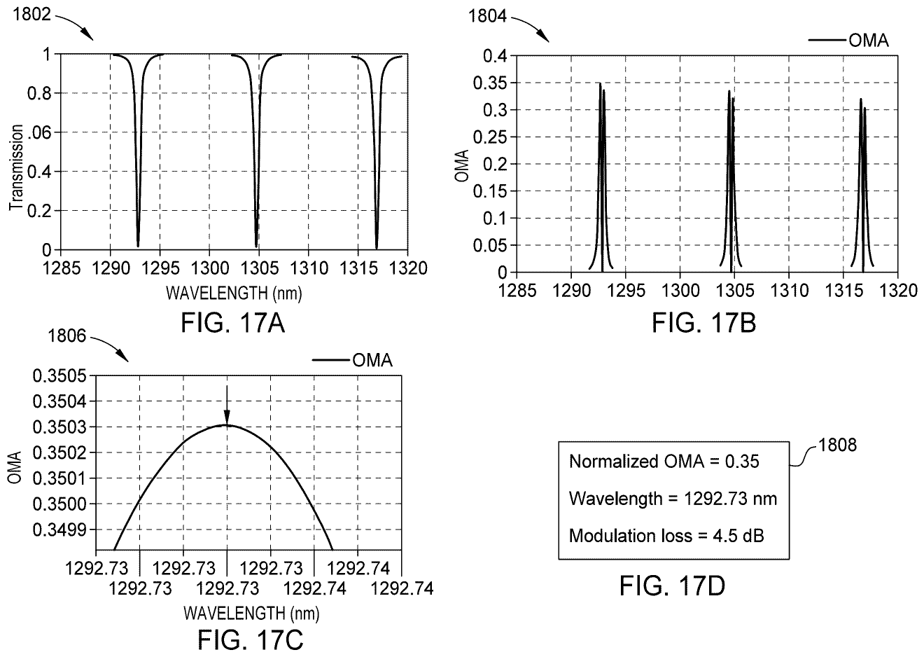

The wavelength that provides the maximum OMA may be selected by maximizing DC OMA, such as depicted in FIGS. 17A through 17D. FIG. 17A depicts a graph 1702 of optical transmission power versus wavelength, according to an embodiment. FIG. 17B depicts a graph 1704 of OMA versus wavelength, according to an embodiment. FIG. 17C depicts a portion 1706 of graph 1704, according to an embodiment. FIG. 17D depicts results 1708, according to an embodiment.

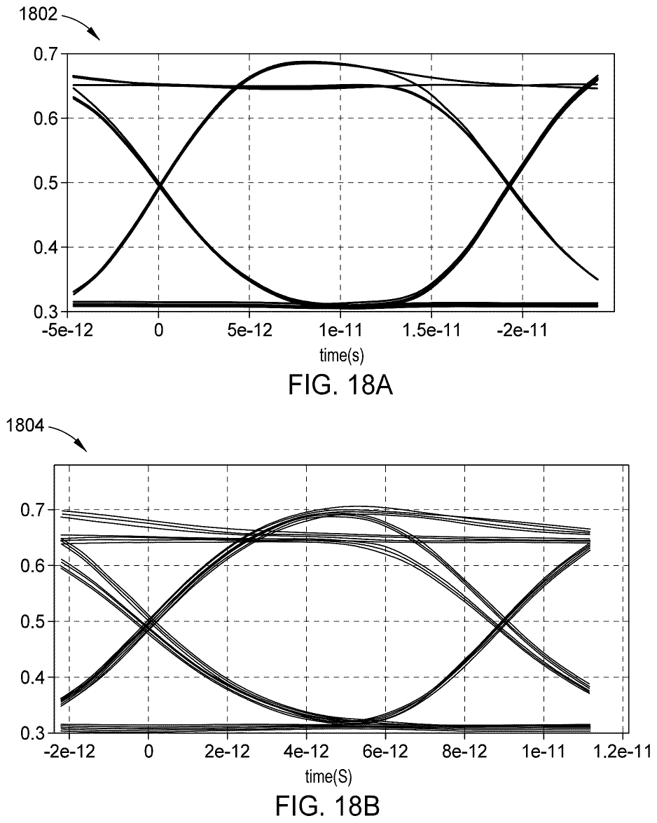

FIG. 18A depicts an eye diagram 1802 for the dual cascaded MRMs, according to an embodiment for which the input wavelength of 1292.73 nm, 0 dBm, and the data rate is 53 Gbits/second, for an OMA of 0.35 and a modulation loss of 4.5 dB. FIG. 18B depicts an eye diagram 1804 for the dual cascaded MRMs, according to another embodiment for which the input wavelength of 1293.73 nm, 0 dBm, and the data rate is 112 Gbits/second, for an OMA of 0.35 and a modulation loss of 4.5 dB. As depicted in FIG. 14B, the dual cascaded MRMs provide higher data rates with no increase in modulation loss, and a higher quality eye opening.

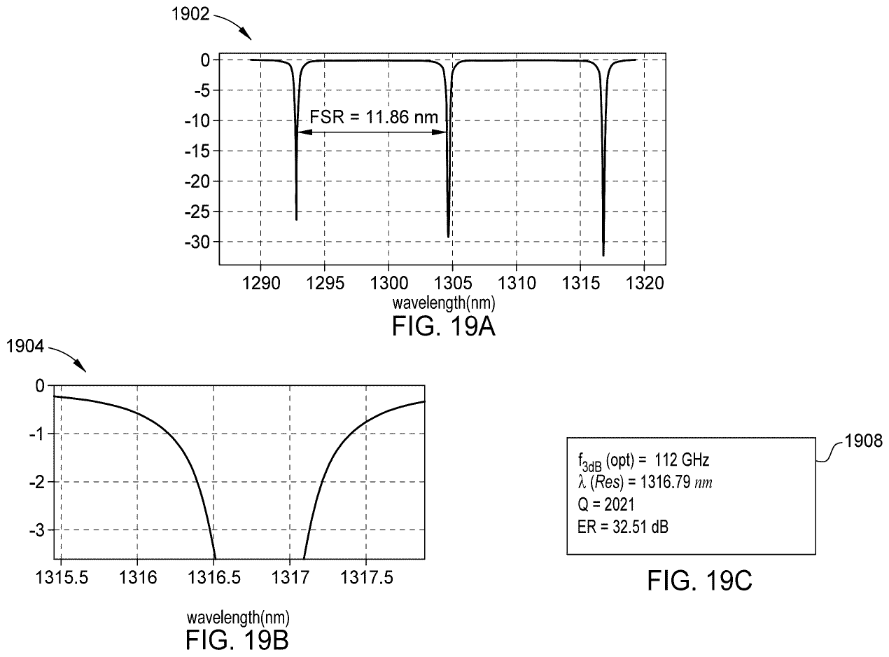

More than two cascaded MRMs further improve optical bandwidth (e.g., which supports higher data rates), such as described below with reference to FIGS. 19A through 19C. FIG. 19A depicts a graph 1902 of throughput response versus wavelength of a triplet of cascaded MRMs, according to an embodiment. FIG. 19B depicts a portion 1904 of graph 1902, centered near 1317 nm, according to an embodiment. FIG. 19C depicts results 1908, according to an embodiment. The triplet cascaded MRMs provide a FSR (i.e., optical bandwidth) of 88.2 nm, with a quality factor of 2554, due to the improved optical bandwidth. The DC ER of the triplet cascaded MRMs increased to 32.51 dB, due to a further increase in slope efficiency.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. An integrated circuit device, comprising:
a throughput waveguide;
multiple micro-ring modulators (MRMs) optically coupled to the throughput waveguide, wherein P junctions of the MRMs are coupled to one another, and wherein N junctions of the MRMs are coupled to one another; and
an inductor coupled to a signal pad and to the N junctions of the MRMs.

2. The integrated circuit device of claim 1, wherein:
radii of the MRMs are equal to one another.

3. The integrated circuit device of claim 2, wherein:
the radii are less than 10 micrometers.

4. The integrated circuit device of claim 1, wherein:
the MRMs are configured to resonant at a same wavelength.

5. The integrated circuit device of claim 1, wherein:
the inductor has an inductance of 0.33Cd(RL+RD)\hat{ }2;
Cd is a capacitance of the MRMs;
RD is a diode resistance of the MRMs; and
RL is an external load resistance.

6. The integrated circuit device of claim 1, further comprising:
a substrate; and
heater elements disposed adjacent to the MRMs;
wherein a surface of the substrate facing the heater elements has recesses aligned with the heater elements.

7. The integrated circuit device of claim 1, further comprising:
a drop port waveguide optically coupled to the MRMs;
wherein optical couplings between the drop port waveguide and the MRMs have shorter distances than optical couplings between the throughput waveguide and the MRMs.

8. The integrated circuit device of claim 1, wherein the MRMs comprise at least two MRMs.

9. The integrated circuit device of claim 1, wherein the MRMs comprise at least three MRMs.

10. The integrated circuit device of claim 1, wherein the MRMs comprise at least four MRMs.

11. The integrated circuit device of claim 1, wherein:
P junctions and N junctions comprise lateral/horizontal junctions.

12. The integrated circuit device of claim 1, wherein:
P junctions and N junctions comprise vertical junctions.

13. The integrated circuit device of claim 1, wherein:
P junctions and N junctions comprise interdigitated junctions.

14. An integrated circuit device, comprising:
a functional circuit; and
an optical transceiver configured to modulate an optical signal based on data from the functional circuit, wherein the optical transceiver comprises:
a throughput waveguide;
multiple micro-ring modulators (MRMs) optically coupled to the throughput waveguide, wherein P junctions of the MRMs are coupled to one another, and wherein N junctions of the MRMs are coupled to one another; and
an inductor coupled to a signal pad and to the N junctions of the MRMs.

15. The integrated circuit device of claim 14, wherein:
radii of the MRMs are equal to one another.

16. The integrated circuit device of claim 15, wherein:
the radii are less than 10 micrometers.

17. The integrated circuit device of claim 14, wherein:
the MRMs are configured to resonant at a same wavelength.

18. The integrated circuit device of claim 14, wherein:
the inductor has an inductance of 0.33Cd(RL+RD)2;
Cd is a capacitance of the MRMs;
RD is a diode resistance of the MRMs; and
RL is an external load resistance.

19. The integrated circuit device of claim 14, further comprising:
a substrate; and
heater elements disposed adjacent to the MRMs;
wherein a surface of the substrate facing the heater elements has recesses aligned with the heater elements.

20. The integrated circuit device of claim 14, wherein P junctions and N junctions comprise one or more of:
lateral/horizontal junctions;
vertical junctions; and
interdigitated junctions.
